(19) United States
(12) Patent Application Publication
(10) Pub. No.: US 2008/0023837 A1
(43) Pub. Date: Jan. 31, 2008

(54) METHOD FOR FABRICATING INTERCONNECT AND INTERCONNECT FABRICATED THEREBY

(75) Inventor: Kun-Hong Chen, Taipei County (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: AU OPTRONICS CORP., Hsinchu (TW)

(21) Appl. No.: 11/865,987

(22) Filed: Oct. 2, 2007

Related U.S. Application Data
(62) Division of application No. 10/785,176, filed on Feb. 23, 2004.

(51) Int. Cl. H01L 23/532; H01L 21/768

(52) U.S. Cl. 257/758; 438/637; 257/E23.154; 257/E21.577; 257/E21.585

(57) ABSTRACT

A Method for discharge prevention during interconnection. A first metal layer is formed on a substrate and a dielectric layer is then formed on the substrate, covering the first metal layer. Two via holes are formed in the dielectric layer, exposing one end of the first metal layer, wherein the first via hole is nearer the end of the first metal layer than the second via hole. The second via hole is then filled to form a conductive via plug to electrically connect the first meal layer. A second metal layer is formed on the dielectric layer to electrically connect the conductive via plug.

### CROSS REFERENCE TO RELATED APPLICATIONS

This application is a divisional application of pending U.S. patent application Ser. No. 10/785,176, filed on Feb. 23, 2004 and entitled “Method For Fabricating Interconnect And Interconnect Fabricated Thereby”, incorporated herein by reference.

### BACKGROUND OF THE INVENTION

1. Field of the Invention

The present invention relates to an interconnect structure, and in particular to discharge prevention during interconnection, utilized in various applications such as a thin film transistor (TFT) array substrate of a liquid crystal display (LCD) panel or conventional electronic circuits.

2. Description of the Related Art

A typical TFT-LCD panel comprises an upper and a lower substrate with liquid crystal materials filled therebetween. The upper substrate (in reference to a user's viewpoint) is typically known as a color filter substrate and the lower substrate is an array substrate having thin film transistors thereon. A backlight unit is located at the back of the panel to provide a light source. When voltage is applied to a transistor, the alignment of the liquid crystal is altered, allowing light to pass through to form a pixel. The front substrate, i.e. the color filter substrate, gives each pixel its own color. The combination of these pixels in different colors forms images displayed on the panel.

In addition to TFT array on the display area, other circuits may be also disposed on the non-display area of the lower substrate, such as driving circuits, scanning circuits and electrostatic discharge (ESD) protection circuits. The peripheral circuits on the non-display area can either be fabricated simultaneously with or separately from the TFT array on the display area.

FIG. 1 is a cross-section of a conventional interconnect structure of a partial peripheral circuit in a non-display area of a TFT-array substrate. A dielectric layer 110, an oxide layer 120, a first metal layer 130, a buffer layer 140 and a second metal layer 152 are disposed sequentially on the surface of the non-display area of a TFT array glass substrate 100. The first metal layer 130 and the second metal layer 152 are interconnected with via plug 150. However, the interface between the first metal layer 130 and via plug 150 are often damaged. In some serious cases, connections between metal layers and via plugs thereon maybe broken, thereby affecting interconnection and reducing the yield of TFT array panels.

### SUMMARY OF THE INVENTION

The primary object of the present invention is to provide a method for fabricating an interconnect structure to avoid discharge damage between metal layers and via plugs thereon.

To achieve the object, the present invention provides a method for fabricating an interconnect structure, and the interconnect structure fabricated thereby. According to the invention, a first metal layer with two ends is formed on a substrate. A dielectric layer is formed, covering the first metal layer. At least two via holes are formed inline on the dielectric layer exposing one end of the first metal layer. The second via hole, farther from the end point of the first metal line, is filled with a conductive material to form a conductive via plug. A second metal layer is formed on the dielectric layer to connect the first metal layer by way of the conductive via plug.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is cross-section of a conventional interconnect structure;

FIGS. 2A to 2C are cross-sections of an interconnect structure according to one embodiment of the invention;

FIG. 2D is a top view of FIG. 2C, wherein FIG. 2C is a cross-section of FIG. 2D along line 1-1;

FIG. 3A is a top view of an interconnect structure according to another embodiment of the invention; and

FIG. 3B is a cross-section of FIG. 3A along line 1-1.

### DETAILED DESCRIPTION OF THE INVENTION

The following description discloses the best-contemplated mode of carrying out the invention. This description is made for the purpose of illustrating the general principles of the invention and should not be taken in a limiting sense. The scope of the invention is best determined by reference to the appended claims.

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers.

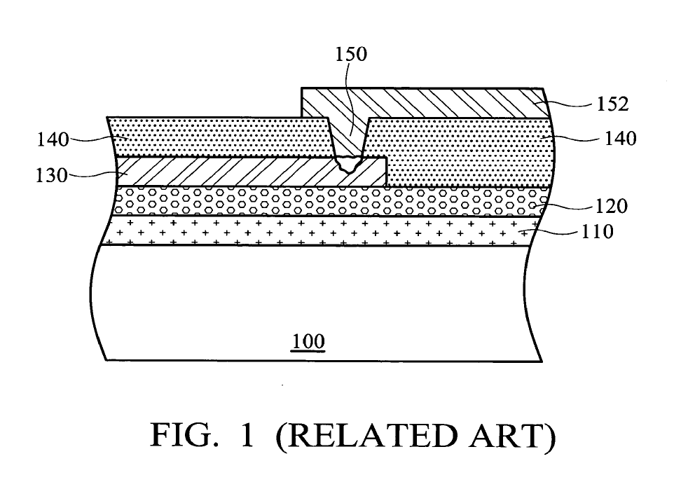

Generally, during fabrication of metal interconnect, electrostatic charges may accumulate on the surface of metal layers due to plasma etching, ion bombardment or photo process. The amount of charge accumulated depends on the surface area or length of the metal layer. Because the scale of TFT-LCD panels exceeds conventional electric circuits, wiring of the peripheral circuits on the TFT-array substrate can be longer than that of conventional circuits. It is found that interconnect breakage as shown in FIG. 1 may be caused by point discharge. Using the interconnect structure shown in FIG. 1 for example, before connecting to the higher metal layer 152, charges induced in previous process accumulate on the surface of the lower metal layer 130, especially at the end points of the metal layer 130. The longer the metal layer 130, the more charges accumulate. When a via opening is formed on the end point of the first metal layer 130 to form a via plug 150 connecting an upper second metal layer 152, point discharge may occur. The charges accumulated on the surface of the metal layer 130 discharge through the via opening on the end points and directly damage the interface between the via plug 150 and the metal layer 130, affecting connection therebetween and possibly terminating connection.

To solve the problem, two preferred embodiments of the invention are provided herein.

### FIRST EMBODIMENT

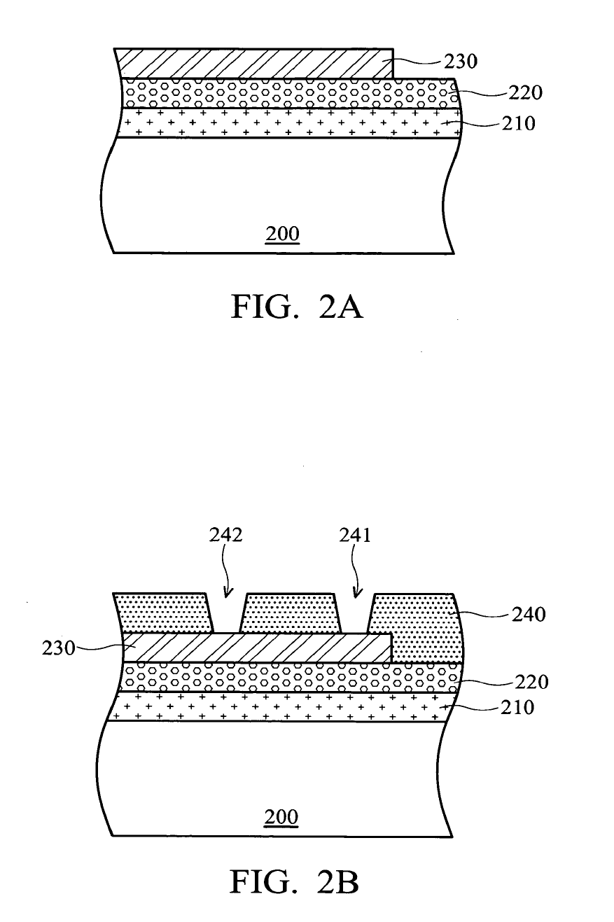

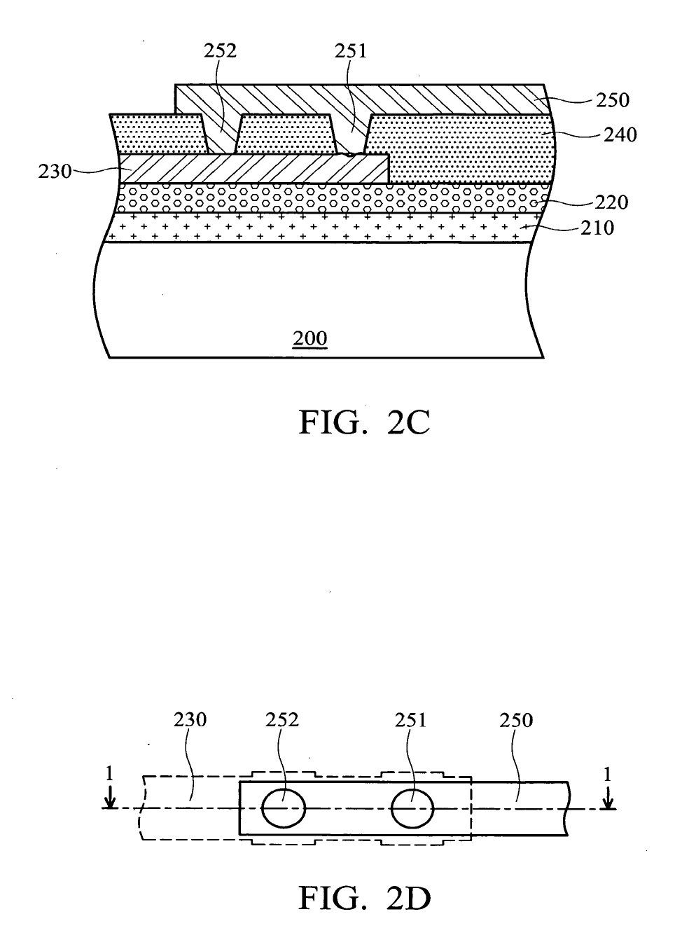

FIGS. 2A to 2C are cross-sections of an interconnect fabrication on a TFT array substrate for an LCD panel. An interconnect structure is fabricated on a non-display area of TFT array substrate 200, which can either be formed simultaneously with or separately from the fabrication of a TFT array on the display area. The process disclosed hereinafter is fabricated simultaneously with the TFT array on the display area (not shown).

As shown in FIG. 2A, a dielectric layer is blanketly formed as a buffer layer 210, such as a silicon oxide layer, covering a surface of a TFT array glass substrate 200. A gate oxide layer 220 is blanketly deposited on the surface of the buffer layer 210. A patterned metal layer 230, having a first and second end, is formed on the surface of the gate oxide layer 220, wherein the direction extending from the first end to the second end is parallel to the substrate 200 surface. The patterned metal layer 230 may be formed simultaneously with gate metal process.

Another dielectric layer 240 with a flat surface is then formed, covering the surface of the metal layer 230 and the gate oxide layer 220, as an interlayer dielectric (ILD) layer. At least two via holes 241 and 242 parallel to extending direction of the metal layer 230 are formed inline in the dielectric layer 240, exposing the underlying metal layer 230 as shown in FIG. 2B.

The via holes 251 and 252 are then filled with metal to form conductive via plugs 251 and 252 on the metal layer 230. A second level of metal layer can be fabricated as well on the surface of the dielectric layer 240 to form a metal layer 250, connected to the metal layer 230 by via plugs 251 and 252, as shown in FIG. 2C. Via plugs 251 and 252 can be formed simultaneously with the metal layer 250. Alternatively, via plugs 251 and 252 can be formed by filling a conductive material different from the metal layer 250 into via holes 241 and 242. Preferably, the metal layer 250 is formed simultaneously with the source/drain metal process of the TFT array on the display area.

FIG. 2D is a top view of the interconnection of FIG. 2C. The upper metal line 250 is connected to the lower metal line by both the conductive via plugs 251 and 252, wherein the via plug 251 is closer to the end point of the metal line 230 than the via plug 252. More than one via plug is provided on the end point of the lower metal line 230 to electrically connect the upper metal line 250. Even if electrostatic charges are accumulated on the surface of the metal layer 230 during processing, causing point discharge breaking via plug 251 on the end point of the metal line 230 during interconnection, via plug 252 farther from the end point of the metal layer 230 is still kept intact because the electrostatic charges affect the via closest to the end point of the metal layer 230. While via plug 251 on the end of the metal layer 230 may be damaged during point discharge, the upper metal layer 250 is still connected to the lower metal layer 230 by via plug 252 farther from the end point.

### SECOND EMBODIMENT

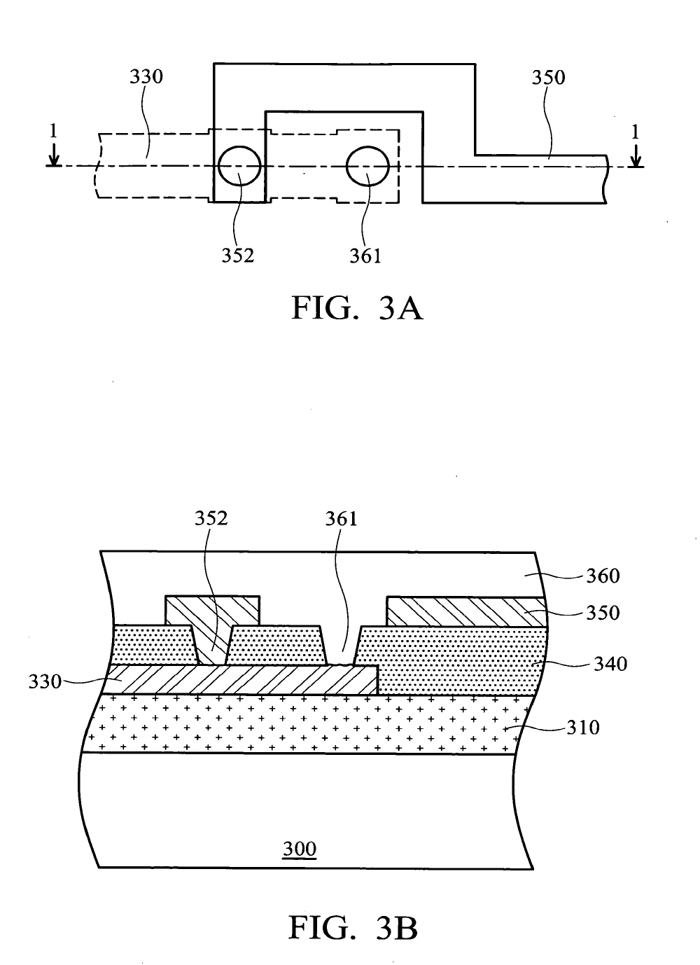

FIGS. 3A and 3B show two different aspects of an interconnect structure in accordance with another embodiment of the invention. FIG. 3A is a top view of the interconnect, wherein two via plugs 352 and 361 are formed on one end of metal layer 330 and via plug 361 is nearer the end point of metal layer 330 than via plug 352. The upper metal layer 350 bypasses via plug 361 to connect the lower metal layer 330 by via plug 352.

FIG. 3B is a cross-section of FIG. 3A along line 1-1. A dielectric layer 310, such as a laminated oxide layer, is formed on a substrate, e.g. a TFT array substrate 300 for an LCD panel. Metal layer 330 is formed and pattered on the dielectric layer 310 as a conductive line, wherein the direction extending from one end of the metal layer 330 to the other end thereof is parallel to the substrate surface. Another flat dielectric layer 340 is formed on the dielectric layer 310 and covers the metal layer 330. Two via holes parallel to extending direction of the metal layer 330 are formed in the dielectric layer 340 above and exposing one end of the metal layer 310.

Despite electrostatic charges accumulated on the surface of the metal layer 330 during processing, causing point discharge on the via hole closest to the end point of the metal line 330, the conductive via plug 352 farther from the end point of the metal layer 330 is remains intact because the static charges are discharged through the via opening nearest the end point of the metal layer 330. Though the section of the end of the metal layer 230, i.e. what underlying via plug 361, may be damaged during point discharge of the metal layer 330, the upper metal layer 350 is still connected to the lower metal layer 330 by the conductive via plug 352 farther from the end point of the metal layer 330.

Although point discharge phenomenon is more prevalent in interconnect fabrication of peripheral circuits on TFT array substrates for LCD panels because of the long wiring, it may also occur in and cause damage to conventional electrical circuits. Thus, the invention can also be applied to conventional circuits to protect interconnection from damage from point discharge, by forming plural via holes on the end of a metal line before connecting to an upper conductive layer.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating an interconnect structure for electrostatic discharge protection, comprising the steps of:
forming a first metal line on a substrate;
forming a dielectric layer on the substrate, covering the first metal line;
forming a first and second via hole in the dielectric layer exposing one end of the first metal line, wherein the first via hole is nearer the end of the first metal line than the second via hole;
forming a second metal line on the dielectric layer and filling the second via hole to form a conductive via plug to electrically connect the first metal line; and
forming a second dielectric layer to fill the first via hole and cover the second metal line and the first dielectric layer.

2. The method as claimed in claim 1, wherein the substrate is a TFT-array substrate for an LCD panel.

3. The method as claimed in claim 2, wherein the first metal line is formed simultaneously with a gate metal line of a TFT array.

4. The method as claimed in claim 2, wherein the second metal line is formed simultaneously with a source/drain metal line of a TFT array.

5. The method as claimed in claim 2, wherein the second via hole is filled with the second metal line.

6. The method as claimed in claim 2, wherein the second metal line is formed to bypass the first via hole.

7. An interconnect structure for electrostatic discharge protection, comprising:
a substrate;
a first dielectric layer disposed on the substrate;
a first metal line disposed in the first dielectric layer, having a first end and a second end, wherein the direction extending from the first end to the second end is parallel to a surface of the substrate;
a first plug and a second plug disposed on the first end of the first metal line, wherein the first plug is non-conductive, the second plug is conductive, and wherein the first plug is closer to the first end than the second plug; and
a second metal line disposed on the first dielectric layer, connecting the first metal line through the second plug; and
a second dielectric layer disposed on the first dielectric layer and the second metal line.

8. The interconnect structure for electrostatic discharge protection as claimed in claim 7, wherein the substrate is a TFT-array substrate for an LCD panel.

9. The interconnect structure for electrostatic discharge protection as claimed in claim 7, wherein the second plug electrically connects one end of the second metal line.

10. The interconnect structure for electrostatic discharge protection as claimed in claim 7, wherein despite electrostatic charges are accumulated on a surface of the first metal line.
